(19) United States
(12) Patent Application Publication
(10) Pub. No.: US 2024/0429878 A1
(43) Pub. Date: Dec. 26, 2024

(54) MULTI-PATH AMPLIFICATION CIRCUIT FOR OPERATING IN DIFFERENT POWER MODES

(71) Applicant: QUALCOMM Incorporated, San Diego, CA (US)

(72) Inventors: Lei MA, Palo Alto, CA (US); Antonino SCUDERI, San Diego, CA (US)

(21) Appl. No.: 18/338,729

(22) Filed: Jun. 21, 2023

(51) Int. Cl. H03F 3/21; H03F 1/56

(52) U.S. Cl. CPC H03F 3/211; H03F 1/56; H03F 2200/211; H03F 2200/255; H03F 2200/318; H03F 2200/423; H03F 2200/451; H03F 2203/21127

(57) ABSTRACT

Certain aspects of the present disclosure generally relate to an amplification circuit. The amplification circuit generally includes: a first amplification path comprising a first amplification transistor and coupled between an input node of the amplification circuit and an output node of the amplification circuit; and a second amplification path comprising a second amplification transistor and coupled between the input node and the output node, wherein the second amplification path further includes an attenuator coupled between the input node of the amplification circuit and a control input of the second amplification transistor.

### FIELD OF THE DISCLOSURE

Certain aspects of the present disclosure generally relate to electronic components and, more particularly, to circuitry for signal amplification.

### BACKGROUND

Electronic devices include computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast, and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems (e.g., a Long Term Evolution (LTE) system or a New Radio (NR) system). Wireless devices may include transmitters for processing signals for transmission via antennas. A transmitter may include a power amplifier (PA) for amplifying a signal for transmission.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide the advantages described herein.

Certain aspects of the present disclosure are directed towards an amplification circuit. The amplification circuit generally includes: a first amplification path comprising a first amplification transistor and coupled between an input node of the amplification circuit and an output node of the amplification circuit; and a second amplification path coupled between the input node and the output node of the amplification circuit and comprising a second amplification transistor and an attenuator coupled between the input node of the amplification circuit and a control input of the second amplification transistor.

Certain aspects of the present disclosure are directed towards a method for signal amplification. The method generally includes: determining a power mode for an amplification circuit; selecting a first amplification path or a second amplification path based on the determined power mode, wherein the first amplification path includes a first amplification transistor coupled to an output node of the amplification circuit, and wherein the second amplification path includes a second amplification transistor coupled to the output node and an attenuator coupled to a control input of the second amplification transistor; and amplifying an input signal via the first amplification path or the second amplification path based on the selection.

Certain aspects of the present disclosure are directed towards an apparatus for signal amplification. The apparatus generally includes: first means for amplifying an input signal at an input node, the first means for amplifying being coupled between the input node and an output node; means for attenuating the input signal to yield an attenuated signal, the means for attenuating being coupled to the input node; and second means for amplifying the attenuated signal, the second means for amplifying being coupled between the means for attenuating and the output node.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a diagram of an example wireless communications network, in accordance with certain aspects of the present disclosure.

FIG. 2 is a block diagram of an example access point (AP) and example user terminals, in accordance with certain aspects of the present disclosure.

FIG. 3 is a block diagram of an example transceiver front end, in accordance with certain aspects of the present disclosure.

FIG. 4 illustrates an example amplification circuit implemented with multiple amplification paths, in accordance with certain aspects of the present disclosure.

FIG. 5 illustrates an example amplification circuit with multiple amplification paths and a shared current source for implementing different power modes, in accordance with certain aspects of the present disclosure.

FIG. 6 is a flow diagram depicting example operations for signal amplification, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure generally relate to techniques and apparatus for signal amplification using different amplification paths allowing for operating in different power modes. For example, certain aspects provide an amplification circuit that may be operable in a low-power mode (LPM) and a high-power mode (HPM). The amplification circuit may include an amplification path for the LPM and an amplification path for the HPM. The amplification path for the LPM may include an attenuator for generating an attenuated signal for amplification when operating in LPM, whereas the amplification path for the HPM may not include such an attenuator. Having separate amplification paths allows an attenuator to be implemented in the amplification for the LPM with little to no impact on the amplification path for the HPM. A first bias circuit may be used to bias the first amplification path, and a second bias circuit may be used to bias the second amplification path. In some aspects, a current source may be selectively coupled to the first bias circuit or the second bias circuit based on whether the amplification circuit is operating in LPM or HPM. In some aspects, an on-die HBT transistor may be used to function as an attenuator. For example, the attenuator may be tunable via a transistor (e.g., a heterojunction bipolar transistor (HBT)) and the transistor may be implemented on the same semiconductor die as a drive amplifier (DA) and/or power amplifier (PA) for the signal amplification.

### Example Wireless Communications

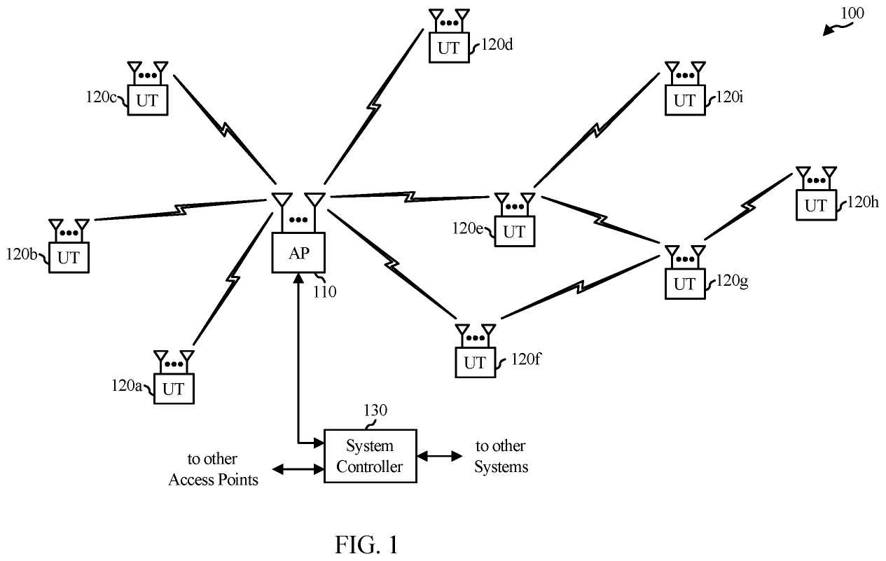

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), a next generation Node B (gNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

Wireless communications system 100 employs multiple transmit and multiple receive antennas for data transmission on the downlink and uplink. Access point 110 may be equipped with a number Nap of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≥1). The Nᵤ selected user terminals can have the same or different number of antennas.

Wireless communications system 100 may be a time division duplex (TDD) system or a frequency division duplex (FDD) system. For a TDD system, the downlink and uplink share the same frequency band. For an FDD system, the downlink and uplink use different frequency bands. Wireless communications system 100 may also utilize a single carrier or multiple carriers for transmission. Each user terminal 120 may be equipped with a single antenna (e.g., to keep costs down) or multiple antennas (e.g., where the additional cost can be supported). In some aspects, the user terminal 120 or access point 110 may include an amplifier implemented with multiple amplification paths for operating in different power modes.

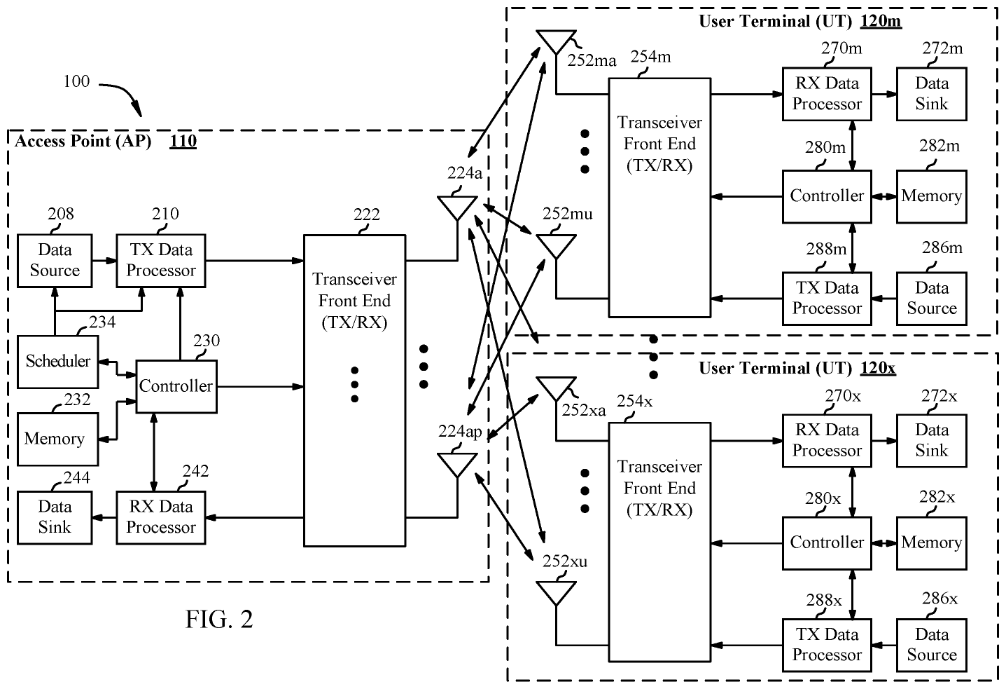

FIG. 2 shows a block diagram of access point 110 and two user terminals 120m and 120x in the wireless communications system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering, beamforming, or some other spatial processing technique may be used at the access point and/or user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. An RX data processor 242 processes (e.g., demodulates, deinterleaves, and decodes) the recovered uplink data symbol stream in accordance with the rate used for that stream to obtain decoded data. The decoded data for each user terminal may be provided to a data sink 244 for storage and/or a controller 230 for further processing.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front end 254 may select signals received from one or more of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal. In some aspects, the transceiver front end 254 or 222 may include an amplifier implemented with multiple amplification paths for operating in different power modes.

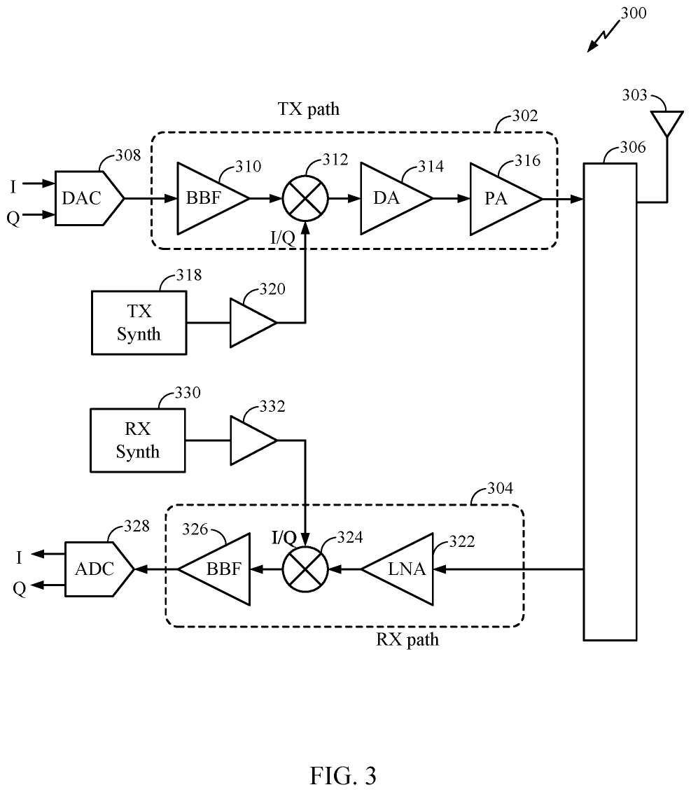

FIG. 3 is a block diagram of an example transceiver front end 300, such as transceiver front ends 222, 254 in FIG. 2, in which aspects of the present disclosure may be practiced. The transceiver front end 300 includes at least one transmit (TX) path 302 (also known as a “transmit chain”) for transmitting signals via one or more antennas and at least one receive (RX) path 304 (also known as a “receive chain”) for receiving signals via the antennas. When the TX path 302 and the RX path 304 share an antenna 303, the paths may be connected with the antenna via an interface 306, which may include any of various suitable radio frequency (RF) devices, such as a switch, a duplexer, a diplexer, a multiplexer, and the like.

Receiving in-phase (I) and/or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, the DA 314, and the PA 316 may be included in a radio frequency integrated circuit (RFIC). In some cases, the PA 316 may be external to the RFIC.

The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 312 are typically RF signals, which may be amplified by the DA 314 and/or by the PA 316 before transmission by the antenna 303. In some aspects, the DA 314 and/or the PA 316 may be implemented with multiple amplification paths for operating in different power modes. While one mixer 312 is illustrated, several mixers may be used to upconvert the filtered baseband signals to one or more intermediate frequencies and to thereafter upconvert the intermediate frequency (IF) signals to a frequency for transmission.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I and/or Q signals for digital signal processing.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO frequency may be produced by a TX frequency synthesizer 318, which may be buffered or amplified by amplifier 320 before being mixed with the baseband signals in the mixer 312. Similarly, the receive LO frequency may be produced by an RX frequency synthesizer 330, which may be buffered or amplified by amplifier 332 before being mixed with the RF signals in the mixer 324. In some cases, a single frequency synthesizer may be used for both the TX path 302 and the RX path 304.

### Example Multi-Path Amplification Circuit

Some wireless devices may use a multi-mode-multi-band (MMMB) power amplifier (PA), such that a single PA can support multiple modes and multiple frequency bands, to save cost and area. A typical MMMB PA shows good performance in high-power mode (HPM) when signal transmission is occurring with high power as the PA may be specifically tuned for HPM. However, in some conditions, the PA may not transmit with high power, and a low-power transmission may be sufficient for a user equipment (UE) to transmit a signal (e.g., to a base station). For a typical PA designed with a 30 dB gain (e.g., implemented by a 2-stage or 3-stage PA) in HPM, in low-power mode (LPM), the PA gain may be high (e.g., even with a lowered rail voltage (Vcc) and reference current (Iref) for the PA), which may cause a problem for meeting a high dynamic range transceiver specification.

Certain aspects of the present disclosure are directed towards an amplifier architecture implemented with an HPM amplification path and an LPM amplification path. With two amplification paths, the HPM performance may be maintained while implementing an attenuator for the LPM. For example, the LPM amplification path may include an attenuator providing tunability for low gain (e.g., with little to no impact on the performance of the HPM amplification path). In other words, if a single amplification path is used for both HPM and LPM and an attenuator is used on the single amplification path, the attenuator may most likely adversely impact the HPM performance. With separate amplification paths (e.g., including separate driver amplifiers (DAs)) for HPM and LPM, the attenuator generates an attenuated signal for the LPM amplification path with a significantly smaller impact on the HPM amplification path, compared to using a single amplification path. While the example attenuation technique described herein is described with respect to multiple amplification paths for driver amplifiers (e.g., referred to as “DA segmentation”), the aspects described herein may additionally or alternatively be implemented with PA segmentation. For example, multiple amplification paths may be used for power amplification with separate bias circuits for the amplification paths, in some aspects.

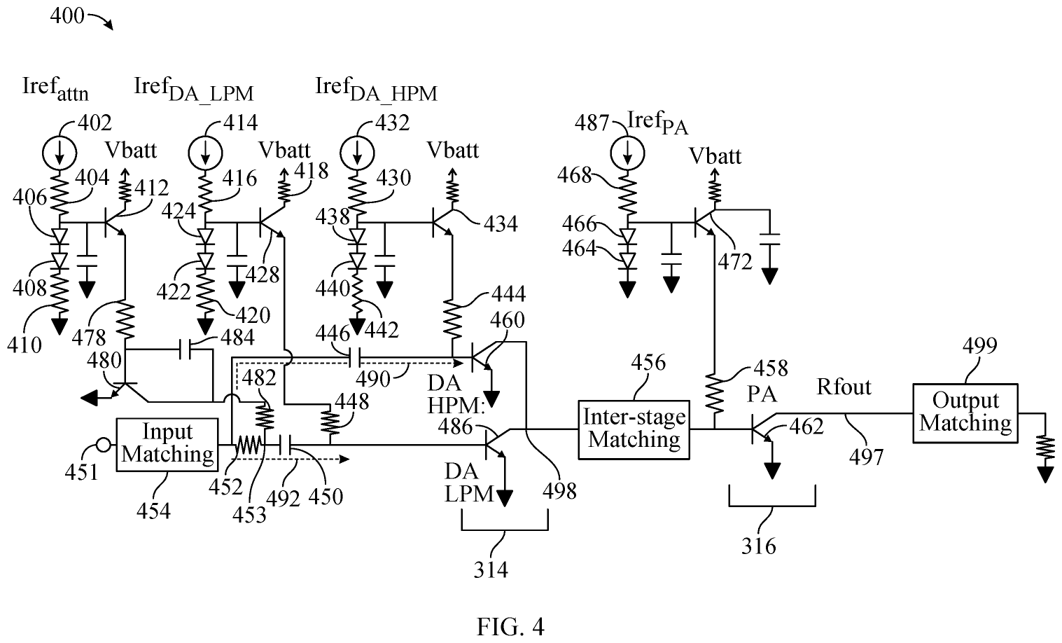

FIG. 4 illustrates an example amplification circuit 400 implemented with multiple amplification paths (e.g., DA paths, for implementing a DA, such as DA 314 of FIG. 3), in accordance with certain aspects of the present disclosure. As shown, the amplification circuit 400 may include a PA transistor 462 (e.g., for implementing the PA, such as PA 316 of FIG. 3), a DA transistor 460 (e.g., for implementing a DA for HPM), and a DA transistor 486 (e.g., for implementing a DA for LPM). One or more of the transistors 460, 486, 462 may be implemented as one or more heterojunction bipolar transistors (HBTs). The one or more HBTs may implemented on the same die (e.g., a gallium arsenide (GaAs) die) as the DA transistor 460 and/or PA transistor 462. The DA transistor 460 may be part of an HPM amplification path 490, and the DA transistor 486 may be part of an LPM amplification path 492. The gain associated with each path may be set at least in part using the size of the associated DA transistor. For example, LPM gain may be set using the associated amplification path (e.g., via attenuation) and by configuration of the size of the DA transistor (e.g., transistor 486), which may allow for the LPM gain to be reduced (e.g., as compared to the HPM gain).

Each of the amplification paths 490, 492 may receive a bias signal. For example, a transistor 434 (e.g., also referred to herein as a “bias transistor”) may have an emitter coupled to a base of transistor 460 through a resistive element 444. The collector of transistor 434 may be coupled to a voltage rail (e.g., coupled to a power source such as a battery providing a battery voltage (Vbatt)). A current source 432 may source a reference current (Iref_{DA_HPM}) across a resistive element 430, diodes 438, 440, and a resistive element 442, generating a voltage at the base of transistor 434. Thus, the transistor 434 may be biased, providing a bias signal (e.g., bias current) for biasing the transistor 460.

Similarly, a transistor 428 may have an emitter coupled to a base of transistor 486 through a resistive element 448. The collector of transistor 428 may be coupled to the voltage rail (e.g., through a resistive element 418). A current source 414 may source a reference current (Iref_{DA_LPM}) across a resistive element 416, diodes 422, 424, and a resistive element 420, generating a voltage at the base of transistor 428. Thus, the transistor 428 may be biased, providing a bias signal (e.g., bias current) for biasing the transistor 486.

As shown, the amplification path 490 may include a ballasting capacitive element 446, and the amplification path 492 may include a ballasting capacitive element 450. The collectors of transistors 460, 486 may be coupled to a DA output node 498. The DA output node 498 may be coupled to an input of the PA (e.g., a base of transistor 462) through an inter-stage matching circuit 456 for impedance matching. The collector of transistor 462 may be coupled to an output node 497 (e.g., having an output RF signal labeled “Rfout”) of the PA, providing a signal for transmission (e.g., through an output impedance matching circuit 499). As shown, a reference current (Iref_{PA}) may be provided for biasing the PA (e.g., transistor 462). For example, a transistor 472 may have an emitter coupled to the base of transistor 462 through a resistive element 458. The collector of transistor 472 may be coupled to the voltage rail. A current source 487 may source a reference current (Iref_{PA}) across a resistive element 468 and diodes 464, 466, generating a voltage at the base of transistor 472. Thus, the transistor 472 may be biased, providing a bias signal for biasing the transistor 462.

In some aspects of the present disclosure, an attenuator may be implemented for the LPM amplification path 492. For example, the attenuator may include a resistive element 452 coupled between an input node 451 and node 453. In some aspects, a resistive element 482 may be coupled between node 453 and a collector of a transistor 480. The transistor 480 may be implemented as a HBT (e.g., GaAs transistor). The emitter of transistor 480 may be coupled to a reference potential node (e.g., electrical ground), as shown. An input impedance matching circuit 454 (e.g., for impedance matching) may be coupled between the input node 451 and the resistive element 452.

In some aspects, the transistor 480 may be biased to tune the attenuator. For example, transistor 412 may have an emitter coupled to a base of transistor 480 through a resistive element 478. In some aspects, a capacitive element 484 may be coupled between the base and the collector of transistor 480. The capacitive element 484 may be used to tune the attenuator for a specific frequency band. The collector of transistor 412 may be coupled to the voltage rail, as shown.

A current source 402 may source a reference current (Irefₐₜₜₙ) across a resistive element 404, diodes 406, 408, and a resistive element 410, generating a voltage at the base of transistor 412. Thus, the transistor 412 may be biased, providing a bias signal for biasing transistor 480 to set an attenuation level of the attenuator (e.g., by adjusting the impedance between node 453 and the reference potential node (e.g., electrical ground)). As described, the attenuator is implemented for the LPM amplification path and provides attenuation for operating in LPM with little to no impact on the HPM amplification path.

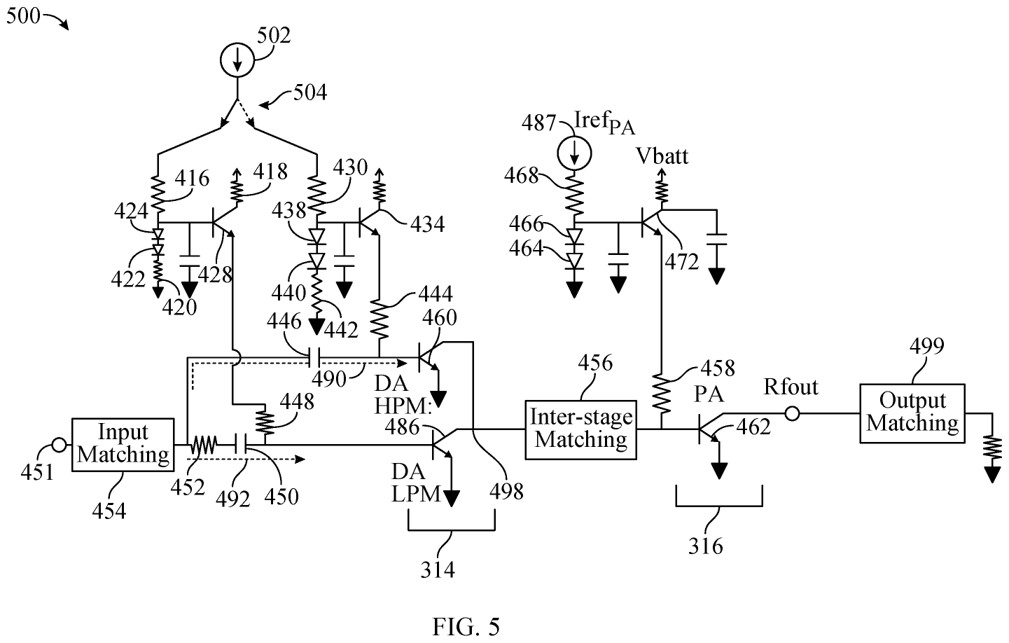

FIG. 5 illustrates an example amplification circuit 500 with multiple amplification paths and a shared current source 502 for LPM and HPM, in accordance with certain aspects of the present disclosure. Reference currents for the amplification circuit 500 may be provided by a residual current device (RCD). By using a same current source 502 for the LPM and HPM, the cost of the RCD may be reduced (e.g., the RCD may not have to provide separate reference currents for the LPM and HPM). The amplification circuit 500 may either operate in LPM or HPM. Therefore, the current source 502 may be selectively coupled (e.g., via switch 504) to resistive element 416 or 430 for biasing either the transistor 428 or the transistor 434. In other words, when current source 502 is coupled to resistive element 416, a voltage is generated at the base of transistor 428, generating a bias signal for the LPM amplification path 492, and when current source 502 is coupled to resistive element 430, a voltage is generated at the base of transistor 434, generating a bias signal for the HPM amplification path 490. By using a common current source 502, the number of current sources for implementing the amplification circuit 500 may be reduced as compared to amplification circuit 400, reducing area and power consumption.

In some aspects, the amplification circuit 500 may be implemented with constant attenuation (e.g., with an attenuator having an attenuation level that is not tunable). For example, the attenuator may include resistive element 452 in the LPM amplification path 492. Implementing the amplification circuit with multiple amplification paths may allow for constant attenuation to be used for LPM (e.g., since amplification path 492 including the attenuator is designated for only LPM operation as opposed to having to support both LPM and HPM).

Certain aspects of the present disclosure provide a dual amplifier implementation for a MMMB PA with an integrated HBT attenuator design that can maintain HPM performance while providing tunability for lowering the gain for the LPM. Programmable LPM gain may be realized with little to no impact on the HPM path. In addition to the attenuator, attenuation may be configured for the LPM amplification path by setting the HBT emitter length and width (e.g., for transistor 428). The dual amplifier implementation described herein can be used to tune the HPM path and the LPM path differently.

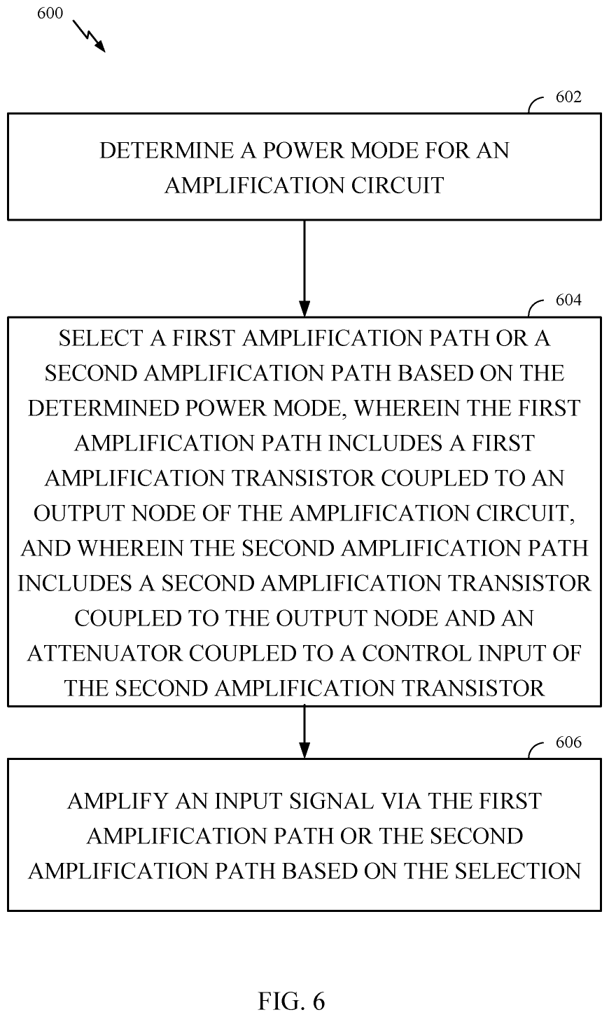

FIG. 6 is a flow diagram depicting example operations 600 for signal amplification, in accordance with certain aspects of the present disclosure. For example, the operations 600 may be performed by an electrical device including an amplification circuit, such as the amplification circuit 400 or amplification circuit 500.

The operations 600 begin, at block 602, with the electrical device determining a power mode (e.g., LPM or HPM) for an amplification circuit. At block 604, the electrical device selects a first amplification path (e.g., amplification path 490) or a second amplification path (e.g., amplification path 492) based on the power mode. The first amplification path may include a first amplification transistor (e.g., transistor 460) coupled to an output node (e.g., output node 498) of the amplification circuit. The second amplification path may include a second amplification transistor (e.g., transistor 486) coupled to the output node and an attenuator (e.g., resistive element 452) coupled to a control input (e.g., gate) of the second amplification transistor. At block 606, the electrical device amplifies an input signal via the first amplification path or the second amplification path based on the selection.

In some aspects, the electrical device attenuates, via the attenuator, the input signal to yield an attenuated signal and amplifies the attenuated signal with the second amplification transistor. The electrical device may determine a level of attenuation associated with the attenuator. The electrical device may generate, via a bias circuit, a bias signal for an attenuation transistor (e.g., transistor 480) of the attenuator based on the level of attenuation. For example, the attenuator may include a resistive element (e.g., resistive element 452) coupled in series between an input node (e.g., input node 451) of the amplification circuit and the control input (e.g., gate) of the second amplification transistor. The attenuation transistor may be coupled between the resistive element and a reference potential node. The electrical device may bias the attenuation transistor with the bias signal. In some aspects, the bias circuit may include a bias transistor (e.g., transistor 412) coupled between a voltage rail and a control input of the attenuation transistor. Generating the bias signal may include sourcing, via a current source, a current to a control input (e.g., gate) of the bias transistor.

In some aspects, the electrical device biases, via a first bias circuit (e.g., transistor 434), the first amplification transistor based on the power mode being a HPM or biases, via a second bias circuit (e.g., transistor 428), the second amplification transistor based on the power mode being a LPM. The first bias circuit may include a first bias transistor (e.g., transistor 434) coupled between a voltage rail and a control input of the first amplification transistor, a control input of the first bias transistor being selectively coupled to a current source (e.g. current source 502). The second bias circuit may include a second bias transistor (e.g., transistor 428) coupled between the voltage rail and a control input of the second amplification transistor, a control input of the second bias transistor being selectively coupled to the current source. In some aspects, the electrical device is configured to selectively couple the current source (e.g., via switch 504) to the first bias transistor or the second bias transistor based on the power mode.

### Example Aspects

Aspect 1: An amplification circuit, comprising: a first amplification path comprising a first amplification transistor and coupled between an input node of the amplification circuit and an output node of the amplification circuit; and a second amplification path coupled between the input node and the output node of the amplification circuit and comprising a second amplification transistor and an attenuator coupled between the input node of the amplification circuit and a control input of the second amplification transistor.

Aspect 2: The amplification circuit of Aspect 1, wherein the attenuator comprises a first resistive element coupled in series between the input node and the control input of the second amplification transistor.

Aspect 3: The amplification circuit of Aspect 2, wherein the attenuator further comprises an attenuation transistor coupled between the first resistive element and a reference potential node.

Aspect 4: The amplification circuit of Aspect 3, wherein the attenuator further comprises a second resistive element coupled between the first resistive element and the reference potential node.

Aspect 5: The amplification circuit of Aspect 3 or 4, further comprising a bias circuit coupled to a control input of the attenuation transistor.

Aspect 6: The amplification circuit of Aspect 5, wherein the bias circuit comprises a bias transistor coupled between a voltage rail and the control input of the attenuation transistor, a control input of the bias transistor being coupled to a current source.

Aspect 7: The amplification circuit of Aspect 5 or 6, wherein the attenuation transistor includes a heterojunction bipolar transistor (HBT).

Aspect 8: The amplification circuit according to any of Aspects 3-7, wherein the attenuation transistor is on a same semiconductor die as the first amplification transistor, and wherein the attenuation transistor and the first amplification transistor are gallium arsenide (GaAs) transistors.

Aspect 9: The amplification circuit according to any of Aspects 1-8, wherein: the first amplification path includes a first driver amplifier (DA) segment comprising the first amplification transistor; the second amplification path includes a second DA segment comprising the second amplification transistor; and the amplification circuit further comprises a power amplifier (PA) having an input coupled to outputs of the first DA segment and the second DA segment.

Aspect 10: The amplification circuit according to any of Aspects 1-9, further comprising: a first bias circuit coupled to a control input of the first amplification transistor; and a second bias circuit coupled to the control input of the second amplification transistor.

Aspect 11: The amplification circuit of Aspect 10, wherein: the first bias circuit is configured to bias the first amplification transistor based on the amplification circuit operating in a high-power mode (HPM); and the second bias circuit is configured to bias the second amplification transistor based on the amplification circuit operating in a low-power mode (LPM).

Aspect 12: The amplification circuit of Aspect 10 or 11, wherein: the first bias circuit includes a first bias transistor coupled between a voltage rail and a control input of the first amplification transistor, a control input of the first bias transistor being coupled to a first current source; and the second bias circuit includes a second bias transistor coupled between the voltage rail and a control input of the second amplification transistor, a control input of the second bias transistor being coupled to a second current source.

Aspect 13: The amplification circuit of Aspect 12, wherein the first current source and the second current source comprise a same current source selectively coupled to the control input of the first bias transistor or the control input of the second bias transistor.

Aspect 14: The amplification circuit according to any of Aspects 1-13, further comprising: a first capacitive element coupled between the input node and a control input of the first amplification transistor; and a second capacitive element coupled between the input node and the control input of the second amplification transistor.

Aspect 15: A method for signal amplification, comprising: determining a power mode for an amplification circuit; selecting a first amplification path or a second amplification path based on the determined power mode, wherein the first amplification path includes a first amplification transistor coupled to an output node of the amplification circuit, and wherein the second amplification path includes a second amplification transistor coupled to the output node and an attenuator coupled to a control input of the second amplification transistor; and amplifying an input signal via the first amplification path or the second amplification path based on the selection.

Aspect 16: The method of Aspect 15, further comprising: attenuating, via the attenuator, the input signal to yield an attenuated signal; and amplifying the attenuated signal with the second amplification transistor.

Aspect 17: The method of Aspect 16, further comprising: determining a level of attenuation associated with the attenuator; generating, via a bias circuit, a bias signal for an attenuation transistor of the attenuator based on the level of attenuation, wherein the attenuator includes a resistive element coupled in series between an input node of the amplification circuit and the control input of the second amplification transistor, the attenuation transistor being coupled between the resistive element and a reference potential node; and biasing the attenuation transistor with the bias signal.

Aspect 18: The method of Aspect 17, wherein: the bias circuit comprises a bias transistor coupled between a voltage rail and a control input of the attenuation transistor; and generating the bias signal includes sourcing, via a current source, a current to a control input of the bias transistor.

Aspect 19: The method of Aspect 17 or 18, wherein the attenuation transistor includes a heterojunction bipolar transistor (HBT).

Aspect 20: The method according to any of Aspects 15-19, further comprising: biasing, via a first bias circuit, the first amplification transistor based on the determined power mode being a high-power mode (HPM); or biasing, via a second bias circuit, the second amplification transistor based on the determined power mode being a low-power mode (LPM).

Aspect 21: The method of Aspect 20, wherein: the first bias circuit includes a first bias transistor coupled between a voltage rail and a control input of the first amplification transistor, a control input of the first bias transistor being coupled to a current source; the second bias circuit includes a second bias transistor coupled between the voltage rail and a control input of the second amplification transistor, a control input of the second bias transistor being coupled to the current source; and the method further comprises selectively coupling the current source to the first bias transistor or the second bias transistor based on the power mode.

Aspect 22: An apparatus for signal amplification, comprising: first means for amplifying an input signal at an input node, the first means for amplifying being coupled between the input node and an output node; means for attenuating the input signal to yield an attenuated signal, the means for attenuating being coupled to the input node; and second means for amplifying the attenuated signal, the second means for amplifying being coupled between the means for attenuating and the output node.

Aspect 23: The apparatus of Aspect 22, further comprising: means for determining a power mode for the apparatus; and means for selecting the first means for amplifying the input signal or the second means for amplifying the attenuated signal based on the determined power mode.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another-even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112 (f) unless the element is expressly recited using the phrase “means for” or, in the case of a method claim, the element is recited using the phrase “step for.” For example, means for determining may a digital controller such as digital controller 510. Means for generating one or more currents may include a calibration DAC, such as the calibration DAC 802.

It is to be understood that the claims are not limited to the precise configuration and components illustrated above. Various modifications, changes and variations may be made in the arrangement, operation and details of the methods and apparatus described above without departing from the scope of the claims.

1. An amplification circuit, comprising:
a first amplification path comprising a first amplification transistor and coupled between an input node of the amplification circuit and an output node of the amplification circuit; and
a second amplification path coupled between the input node and the output node of the amplification circuit and comprising a second amplification transistor and an attenuator coupled between the input node of the amplification circuit and a control input of the second amplification transistor.

2. The amplification circuit of claim 1, wherein the attenuator comprises a first resistive element coupled in series between the input node and the control input of the second amplification transistor.

3. The amplification circuit of claim 2, wherein the attenuator further comprises an attenuation transistor coupled between the first resistive element and a reference potential node.

4. The amplification circuit of claim 3, wherein the attenuator further comprises a second resistive element coupled between the first resistive element and the reference potential node.

5. The amplification circuit of claim 3, further comprising a bias circuit coupled to a control input of the attenuation transistor.

6. The amplification circuit of claim 5, wherein the bias circuit comprises a bias transistor coupled between a voltage rail and the control input of the attenuation transistor, a control input of the bias transistor being coupled to a current source.

7. The amplification circuit of claim 5, wherein the attenuation transistor includes a heterojunction bipolar transistor (HBT).

8. The amplification circuit of claim 3, wherein the attenuation transistor is on a same semiconductor die as the first amplification transistor, and wherein the attenuation transistor and the first amplification transistor are gallium arsenide (GaAs) transistors.

9. The amplification circuit of claim 1, wherein:
the first amplification path includes a first driver amplifier (DA) segment comprising the first amplification transistor;
the second amplification path includes a second DA segment comprising the second amplification transistor; and
the amplification circuit further comprises a power amplifier (PA) having an input coupled to outputs of the first DA segment and the second DA segment.

10. The amplification circuit of claim 1, further comprising:
a first bias circuit coupled to a control input of the first amplification transistor; and
a second bias circuit coupled to the control input of the second amplification transistor.

11. The amplification circuit of claim 10, wherein:
the first bias circuit is configured to bias the first amplification transistor based on the amplification circuit operating in a high-power mode (HPM); and
the second bias circuit is configured to bias the second amplification transistor based on the amplification circuit operating in a low-power mode (LPM).

12. The amplification circuit of claim 10, wherein:
the first bias circuit includes a first bias transistor coupled between a voltage rail and a control input of the first amplification transistor, a control input of the first bias transistor being coupled to a first current source; and
the second bias circuit includes a second bias transistor coupled between the voltage rail and a control input of the second amplification transistor, a control input of the second bias transistor being coupled to a second current source.

13. The amplification circuit of claim 12, wherein the first current source and the second current source comprise a same current source selectively coupled to the control input of the first bias transistor or the control input of the second bias transistor.

14. The amplification circuit of claim 1, further comprising:
a first capacitive element coupled between the input node and a control input of the first amplification transistor; and
a second capacitive element coupled between the input node and the control input of the second amplification transistor.

15. A method for signal amplification, comprising:
determining a power mode for an amplification circuit;
selecting a first amplification path or a second amplification path based on the determined power mode, wherein the first amplification path includes a first amplification transistor coupled to an output node of the amplification circuit, and wherein the second amplification path includes a second amplification transistor coupled to the output node and an attenuator coupled to a control input of the second amplification transistor; and
amplifying an input signal via the first amplification path or the second amplification path based on the selection.

16. The method of claim 15, further comprising:
attenuating, via the attenuator, the input signal to yield an attenuated signal; and
amplifying the attenuated signal with the second amplification transistor.

17. The method of claim 16, further comprising:
determining a level of attenuation associated with the attenuator;
generating, via a bias circuit, a bias signal for an attenuation transistor of the attenuator based on the level of attenuation, wherein the attenuator includes a resistive element coupled in series between an input node of the amplification circuit and the control input of the second amplification transistor, the attenuation transistor being coupled between the resistive element and a reference potential node; and
biasing the attenuation transistor with the bias signal.

18. The method of claim 17, wherein:
the bias circuit comprises a bias transistor coupled between a voltage rail and a control input of the attenuation transistor; and
generating the bias signal includes sourcing, via a current source, a current to a control input of the bias transistor.

19. The method of claim 17, wherein the attenuation transistor includes a heterojunction bipolar transistor (HBT).

20. The method of claim 15, further comprising:
biasing, via a first bias circuit, the first amplification transistor based on the determined power mode being a high-power mode (HPM); or
biasing, via a second bias circuit, the second amplification transistor based on the determined power mode being a low-power mode (LPM).

21. The method of claim 20, wherein:
the first bias circuit includes a first bias transistor coupled between a voltage rail and a control input of the first amplification transistor, a control input of the first bias transistor being coupled to a current source;
the second bias circuit includes a second bias transistor coupled between the voltage rail and a control input of the second amplification transistor, a control input of the second bias transistor being coupled to the current source; and
the method further comprises selectively coupling the current source to the first bias transistor or the second bias transistor based on the power mode.

22. An apparatus for signal amplification, comprising:
first means for amplifying an input signal at an input node, the first means for amplifying being coupled between the input node and an output node;
means for attenuating the input signal to yield an attenuated signal, the means for attenuating being coupled to the input node; and
second means for amplifying the attenuated signal, the second means for amplifying being coupled between the means for attenuating and the output node.

23. The apparatus of claim 22, further comprising:
means for determining a power mode for the apparatus; and
means for selecting the first means for amplifying the input signal or the second means for amplifying the attenuated signal based on the determined power mode.
